(19) United States
(12) Patent Application Publication
(10) Pub. No.: US 2010/0259305 A1
(43) Pub. Date: Oct. 14, 2010

(54) INJECTION LOCKED PHASE LOCK LOOPS

(75) Inventors: Jri Lee, Taipei City (TW); Huai-De Wang, Taipei City (TW)

Correspondence Address: QUINTERO LAW OFFICE, PC, 615 Hampton Dr, Suite A202, Venice, CA, 90291, US

(73) Assignee: NATIONAL TAIWAN UNIVERSITY, Taipei (TW)

(21) Appl. No.: 12/648,175

(22) Filed: Dec. 28, 2009

(30) Foreign Application Priority Data
Apr. 8, 2009 (TW) TW098111632

(51) Int. Cl. H03L 7/08

(52) U.S. Cl. 327/157; 327/156

(57) ABSTRACT

A signal generating circuit for generating an output signal is provided. A phase detection circuit is arranged to detect a phase difference between an input reference signal and a feedback signal, and generate a control signal according to the phase difference. An injected controlled oscillator is arranged to receive the control signal and an injection signal and generate the output signal according to the control signal and the injection signal. A frequency of the output signal is proportional to a frequency of the input reference signal, and a frequency of the injection signal does not equal to the frequency of the output signal.

### CROSS REFERENCE TO RELATED APPLICATIONS

This application claims priority of Taiwan Patent Application No. 098111632, filed on Apr. 8, 2009, the entirety of which is incorporated by reference herein.

### BACKGROUND OF THE INVENTION

1. Field of the Invention

The invention relates to an injection locked Phase Lock Loop (PLL), and more particularly to a sub-harmonic injection locked PLL.

2. Description of the Related Art

Phase Lock Loop (PLL) is basically a closed loop frequency control system, wherein operation is based on the phase sensitive detection of the phase differences between a feedback signal and a reference signal. A PLL circuit usually includes a controlled oscillator, a divider, a frequency phase detector (PFD), a charge pump, and a loop filter. The PLL circuit responds to both the frequency and the phase of input signals, automatically raising or lowering the frequency of the controlled oscillator until a feedback signal is matched to a reference signal in both frequency and phase. Specifically, a PLL compares the frequencies of two signals via the PFD and produces a control signal which is proportional to the difference between the input frequencies. The control signal is used to drive a controlled oscillator, such as a voltage-controlled oscillator (VCO), which creates a corresponding output frequency in response to the voltage variation of the control signal. The output frequency is fed through a frequency divider back to the input of the system, producing a negative feedback loop. If the output frequency drifts, the control signal will change accordingly, driving the frequency in the opposite direction so as to reduce errors. Thus, the output is locked to the frequency of the reference signal, which is derived from a crystal oscillator and is very stable in frequency.

However, inherent inaccurate oscillation causes the oscillator frequency to drift around the target frequency, introducing undesired phase noise. FIG. 1 shows the phase noise model of a PLL circuit. The x-axis represents the amount of frequency offset of the oscillator frequency and the y-axis represents the phase noise S_{φ}(ω) corresponding to the frequency offset. As shown in FIG. 1, phase noise increases as the oscillator frequency approaches the target frequency (that is, the frequency offset approaches zero). Thus, the oscillator frequency is most likely to drift around the target frequency. The overall noise in the PLL circuit is greatly increased with the increase in the amount of the phase noise. Therefore, in order to reduce the noise in the PLL circuit, a novel PLL circuit structure, which can greatly improve the phase noise performance of the controlled oscillator and has outstanding tolerance to process voltage and temperature (PVT) variation, is highly required.

### BRIEF SUMMARY OF THE INVENTION

Signal generating circuits are provided. An exemplary embodiment of a signal generating circuit for generating an output signal comprises a phase detection circuit and an injected controlled oscillator. The phase detection circuit is arranged to detect a phase difference between an input reference signal and a feedback signal and generate a control signal according to the phase difference. The injected controlled oscillator is arranged to receive the control signal and an injection signal and generate the output signal according to the control signal and the injection signal. A frequency of the output signal is proportional to a frequency of the input reference signal, and a frequency of the injection signal does not equal to the frequency of the output signal.

Another exemplary embodiment of a signal generating circuit for generating an output signal comprises a first phase detection circuit, a second phase detection circuit, a first injected controlled oscillator and a second injected controlled oscillator. The first phase detection circuit is arranged to detect a phase difference between a first input reference signal and a first feedback signal and generate a first control signal according to the phase difference. The second phase detection circuit is arranged to detect a phase difference between a second input reference signal and a second feedback signal and generate a second control signal according to the phase difference. The first injected controlled oscillator is coupled between the first phase detection circuit and the second phase detection circuit and arranged to receive the first control signal and a first injection signal, and generate a first output signal according to the first control signal and the first injection signal. A frequency of the first output signal is proportional to a frequency of the first input reference signal, and a frequency of the first injection signal does not equal to the frequency of the first output signal. The second injected controlled oscillator is coupled to the second phase detection circuit and arranged to receive the second control signal and a second injection signal and generate a second output signal as the output signal according to the second control signal and the second injection signal. The second input reference signal is one of the first input reference signal or the first output signal, a frequency of the second output signal is larger than and proportional to a frequency of the second input reference signal, and a frequency of the second injection signal does not equal to the frequency of second first output signal.

Another exemplary embodiment of a signal generating circuit for generating a high frequency output signal according to an input reference signal comprises a first stage of circuit and a second stage of circuit. The first stage of circuit comprises a first phase locked loop and a first injection signal. The first phase locked loop is arranged to detect a phase difference between the input reference signal and a first feedback signal to generate a first control signal and comprises a first injected controlled oscillator. The first injected controlled oscillator is arranged to generate a first output signal according to the first control signal and a first injection signal. The first feedback signal is generated according to the first output signal and a frequency of the first output signal is a multiple of a frequency of the first feedback signal. The first injection signal generating circuit is coupled to the first injected controlled oscillator and generates the first injection signal according to a first injection reference signal. An oscillation frequency of the first injected controlled oscillator is larger than and a multiple of a frequency of the first injection signal. The second stage of circuit is coupled to the first stage of circuit and comprises a plurality of stages of cascaded phase locked loops and a plurality of stages of the injection signal generating circuits each corresponding to one of the phase locked loops. Each stage of the injection signal generating circuit is coupled to an injected controlled oscillator of the corresponding phase locked loop and generates an injection signal to the corresponding injected controlled oscillator, and the second stage of circuit outputs an output signal at the last stage of the injected controlled oscillator as the high frequency output signal. An oscillation frequency of each stage of injected controlled oscillator is larger than and a multiple of a frequency of the injection signal generated by the corresponding injection signal generating circuit.

A detailed description is given in the following embodiments with reference to the accompanying drawings.

### BRIEF DESCRIPTION OF DRAWINGS

The invention can be more fully understood by reading the subsequent detailed description and examples with references made to the accompanying drawings, wherein:

FIG. 1 shows the phase noise model of a PLL circuit;

FIG. 2 shows a block diagram of a signal generating circuit according to an embodiment of the invention;

FIG. 3 shows a circuit diagram of the signal generating circuit according to an embodiment of the invention;

FIG. 4 shows an exemplary injection signal generating circuit according to an embodiment of the invention;

FIG. 5 shows signal waveforms according to the embodiment of the invention;

FIG. 6a shows an exemplary spectrum of the output signal according to an embodiment of the invention;

FIG. 6b shows an exemplary frequency spectrum of the injection signal according to the embodiment of the invention;

FIG. 6c shows an exemplary frequency spectrum of the injection signal according to the embodiment of the invention;

FIG. 7 shows an exemplary signal generating circuit according to another embodiment of the invention;

FIG. 8 shows signal waveforms according to the embodiment of the invention; and

FIG. 9 shows a circuit diagram of an oscillator according to an embodiment of the invention.

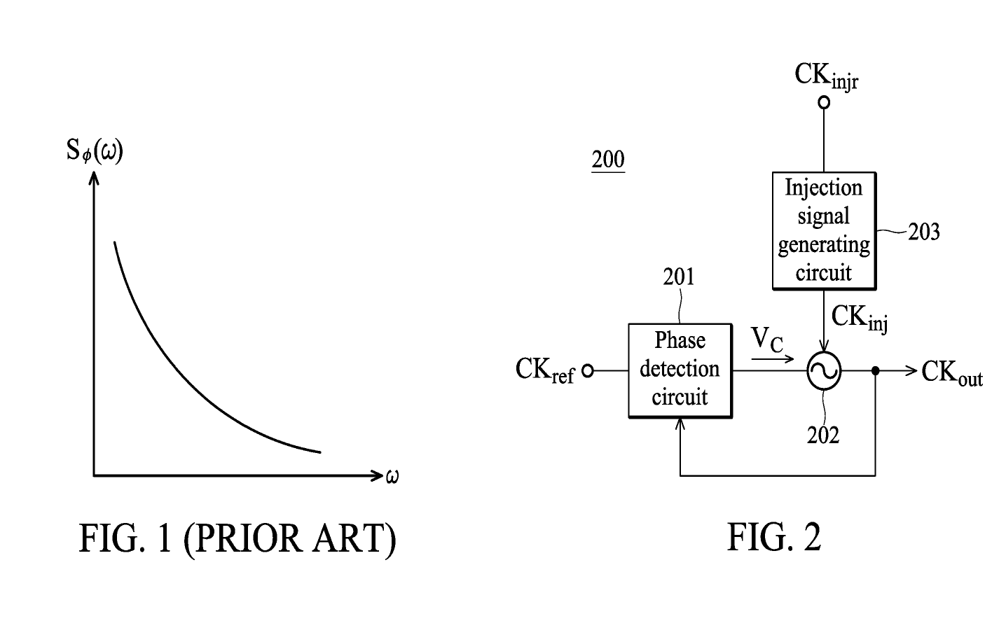

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

FIG. 2 shows a block diagram of a signal generating circuit according to an embodiment of the invention. The signal generating circuit 200 generates an output signal CKₒᵤₜ according to an input reference signal CK_{ref}. A frequency of the output signal CKₒᵤₜ is proportional to a frequency of the input reference signal CK_{ref}. As an example, the frequency of the output signal CKₒᵤₜ may be a multiple of that of the input reference signal CK_{ref}, so as to generate an output signal with multiple times the frequency of the input reference signal CK_{ref}. As shown in FIG. 2, the signal generating circuit 200 comprises a phase detection circuit 201, an oscillator 202 and an injection signal generating circuit 203. The phase detection circuit 201 is arranged to detect a phase difference between the input reference signal CK_{ref} and a feedback signal and generate a control signal V_{c} according to the phase difference. According to an embodiment of the invention, the feedback signal is generated according to the output signal CKₒᵤₜ. Therefore, a frequency of the feedback signal is proportional to that of the output signal CKₒᵤₜ. According to an embodiment of the invention, in order to reduce the inherent phase noise of the oscillator, besides receiving the control signal V_{c}, the oscillator 202 further receives an injection signal CKᵢₙⱼ, and generates the output signal CKₒᵤₜ according to the control signal V_{c} and the injection signal CKᵢₙⱼ. The injection signal generating circuit 203 generates the injection signal CKᵢₙⱼ according to an injection reference signal CKᵢₙⱼᵣ. It is noted that according to an embodiment of the invention, a frequency of the injection signal CKᵢₙⱼ does not equal to that of the output signal CKₒᵤₜ.

According to an embodiment of the invention, frequencies of the injection reference signal CKᵢₙⱼᵣ and the injection signal CKᵢₙⱼ may be smaller than the oscillation frequency of the oscillator 202. As an example, the injection signal generating circuit 203 may inject a sub-harmonic signal of the output signal CKₒᵤₜ to the oscillator 202, or generate the injection signal CKᵢₙⱼ according to the sub-harmonic signal of the output signal CKₒᵤₜ. A signal f2 is regarded as a sub-harmonic signal of a signal f1 when a frequency of the signal f1 is an integer multiple of that of the signal f2.

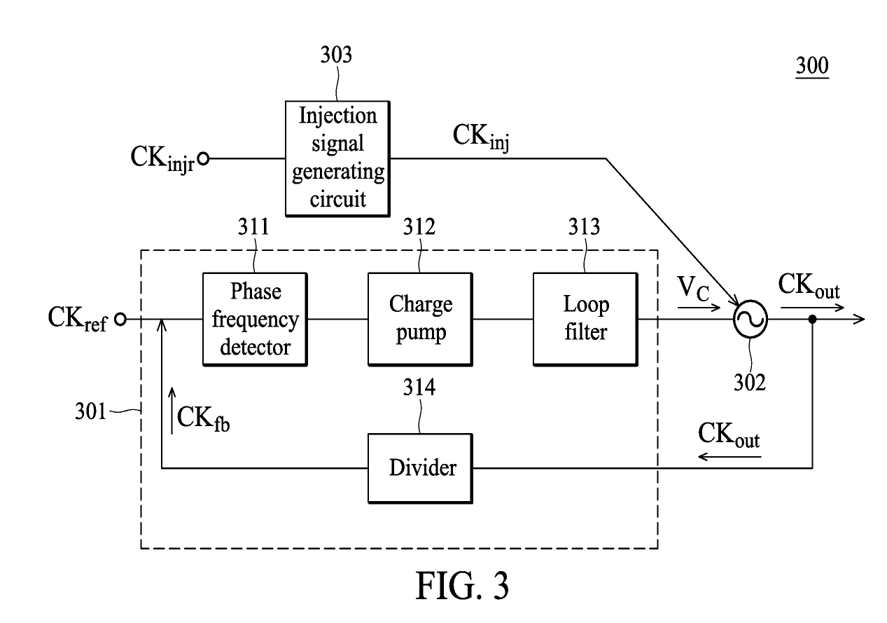

FIG. 3 shows a circuit diagram of the signal generating circuit according to an embodiment of the invention. According to the embodiment of the invention, the signal generating circuit 300 may be implemented as a Phase Locked Loop (PLL), which generates the output signal CKₒᵤₜ by locking the frequency and phase of the input reference signal CK_{ref}. As shown in the figure, the signal generating circuit 300 comprises a phase detection circuit 301, an oscillator 302 and an injection signal generating circuit 303. The phase detection circuit 301 comprises a phase frequency detector 311, a charge pump 312, a loop filter 313 and a divider 314.

The phase frequency detector 311 detects the phase difference between the input reference signal CK_{ref} and the feedback signal CK_{fb}, and generates a phase error signal according to the phase difference. The charge pump 312 generates a current signal according to the phase error signal. The loop filter 313 receives and converts the current signal into the control signal V_{c}. The feedback divider 314 frequency divides frequency of the output signal CKₒᵤₜ to generate the feedback signal CK_{fb}. Therefore, the frequency of the output signal CKₒᵤₜ is a multiple of that of the feedback signal CK_{fb}.

According to an embodiment of the invention, since the injection signal generating circuit may directly inject a sub-harmonic signal of the output signal CKₒᵤₜ into the oscillator, the injection signal generating circuit may directly inject the input reference signal CK_{ref} as the injection signal CKᵢₙⱼ, or directly inject sub-harmonic signals of the output signal CKₒᵤₜ as the injection signal CKᵢₙⱼ. However, according to another embodiment of the invention, the injection signal generating circuit may also be designed non-linearly. As an example, the injection signal generating circuit may receive the input reference signal CK_{ref} or sub-harmonic signals of the output signal CKₒᵤₜ as the injection reference signal CKᵢₙⱼᵣ, and generate the injection signal CKᵢₙⱼ according to the injection reference signal CKᵢₙⱼᵣ.

According to an embodiment of the invention, the non-linear injection signal generating circuit may be designed to generate the injection signal CKᵢₙⱼ, which comprises frequency components at the oscillation frequency of the oscillator. The energy of the output signal CKₒᵤₜ at the oscillation frequency is thus increased due to the injection, so as to reduce the phase noise of the oscillator. As an example, according to an embodiment of the invention, the injection signal generating circuit may be arranged to generate, at each rising edge, each falling edge, or each rising edge and falling edge of the injection reference signal CKᵢₙⱼᵣ, a pulse with a width substantially equal to half of a period length of the output signal CKₒᵤₜ as the injection signal CKᵢₙⱼ. Therefore, the injection signal CKᵢₙⱼ may comprise a plurality of pulses, each having a pulse width substantially equal to half of the period length of the output signal CKₒᵤₜ. However, according to another embodiment of the invention, the pulse width may not be exactly equal to half of the period length of the output signal CKₒᵤₜ. A 50% inaccuracy is tolerable. Therefore, the pulse width may be designed from 25% to 75% of the period length of the output signal CKₒᵤₜ, while still being able to reduce the phase noise of the oscillator.

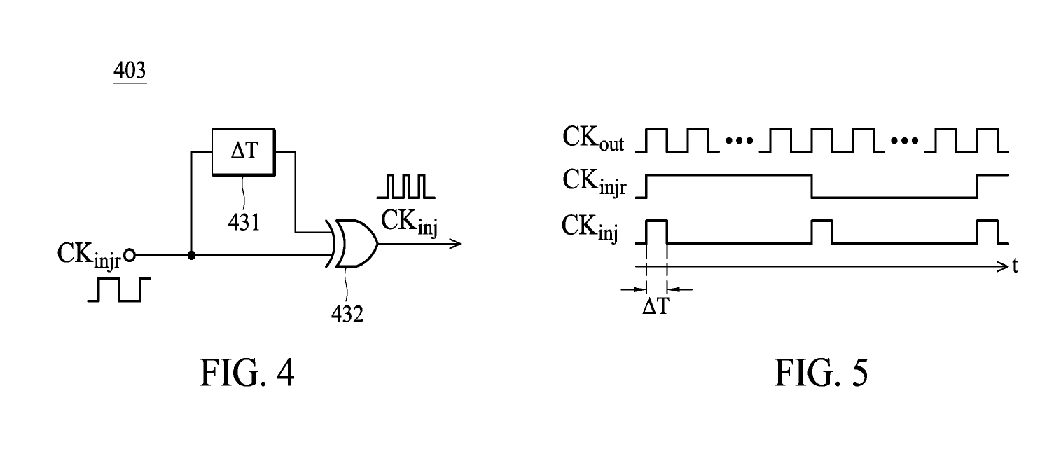

FIG. 4 shows an exemplary injection signal generating circuit according to an embodiment of the invention. The injection signal generating circuit 403 may comprise a delay unit 431 and an XOR gate 432. The delay unit 431 delays the injection reference signal CKᵢₙⱼᵣ for a time period ΔT. The XOR gate 432 comprises two input terminals receiving the injection reference signal CKᵢₙⱼᵣ and the delayed injection reference signal, respectively, and performs XOR operation thereon to generate the injection signal CKᵢₙⱼ. It is noted that in order to compensate for possible delay generated by the electronic components inside of the circuit, extra delay unit(s), as an example, an RC delay, may be used in the exemplary circuits. Therefore, while the invention has been described by way of example and in terms of preferred embodiment, it is to be understood that the invention is not limited thereto. Those who are skilled in this technology can still make various alterations and modifications without departing from the scope and spirit of this invention. The scope of the present invention shall be defined and protected by the following claims and their equivalents

FIG. 5 shows signal waveforms according to the embodiment of the invention. As shown in the figure, the injection reference signal CKᵢₙⱼᵣ is a sub-harmonic signal of the output signal CKₒᵤₜ, and the injection signal CKᵢₙⱼ comprises a plurality of pulses at the rising edges and falling edges of the injection reference signal CKᵢₙⱼᵣ. The pulse width is substantially equal to half of the period length of the output signal CKₒᵤₜ, such as the period ΔT shown in the figure. Therefore, the delay unit 431 may be designed to delay the injection reference signal CKᵢₙⱼᵣ for a time period ΔT, having a length equal to half of the period length of the output signal CKₒᵤₜ. That is,

$$Δ T = \frac{{T}_{CKout}}{2} ,$$

where T_{CKout} is the period length of the output signal CKₒᵤₜ.

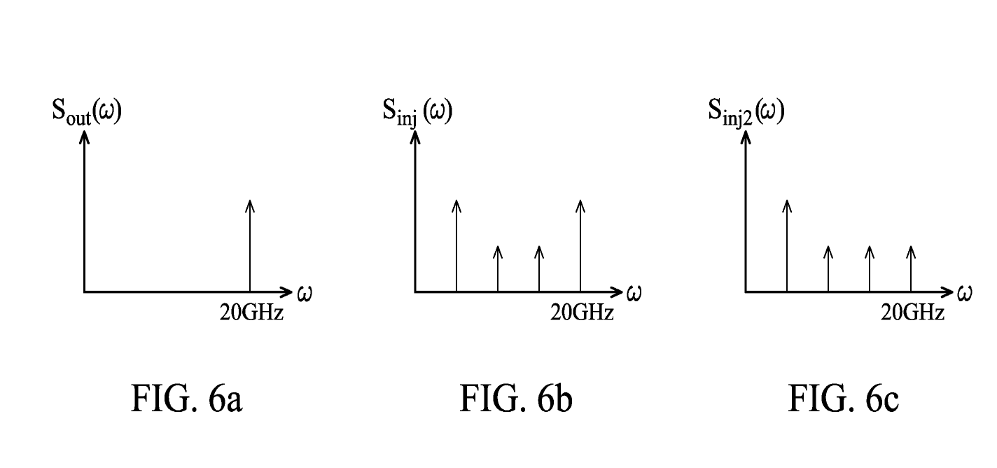

According to the design as illustrated above, when performing Fourier transform on the injection signal CKᵢₙⱼ, the obtained frequency spectrum shows that energy exists at the oscillation frequency of the oscillator. FIG. 6a shows an exemplary frequency spectrum of the output signal CKₒᵤₜ according to an embodiment of the invention. The frequency domain signal Sₒᵤₜ(ω) is obtained by performing the Fourier transforming on the output signal CKₒᵤₜ. Suppose that the output signal CKₒᵤₜ is oscillated at 20 GHz, the frequency domain signal Sₒᵤₜ(ω) comprises the frequency component at 20 GHz as shown in FIG. 6a. FIG. 6b shows an exemplary frequency spectrum of the injection signal CKᵢₙⱼ, generated by the injection signal generating circuit 403, according to the embodiment of the invention. Since the pulses of the injection signal CKᵢₙⱼ is designed to overlap some pulses of the output signal CKₒᵤₜ (reference may be made to FIG. 5), the frequency component at 20 GHz is created. As shown in FIG. 6b, energy exists at 20 GHz frequency component in the frequency spectrum, where frequency domain signal Sᵢₙⱼ(ω) is obtained by performing the Fourier transforming on the injection signal CKᵢₙⱼ. In the embodiment of invention, the delay time period ΔT of the delay unit 431 may be designed by setting

$$Δ T = \frac{1}{2 \times 20 G} = 25 ps .$$

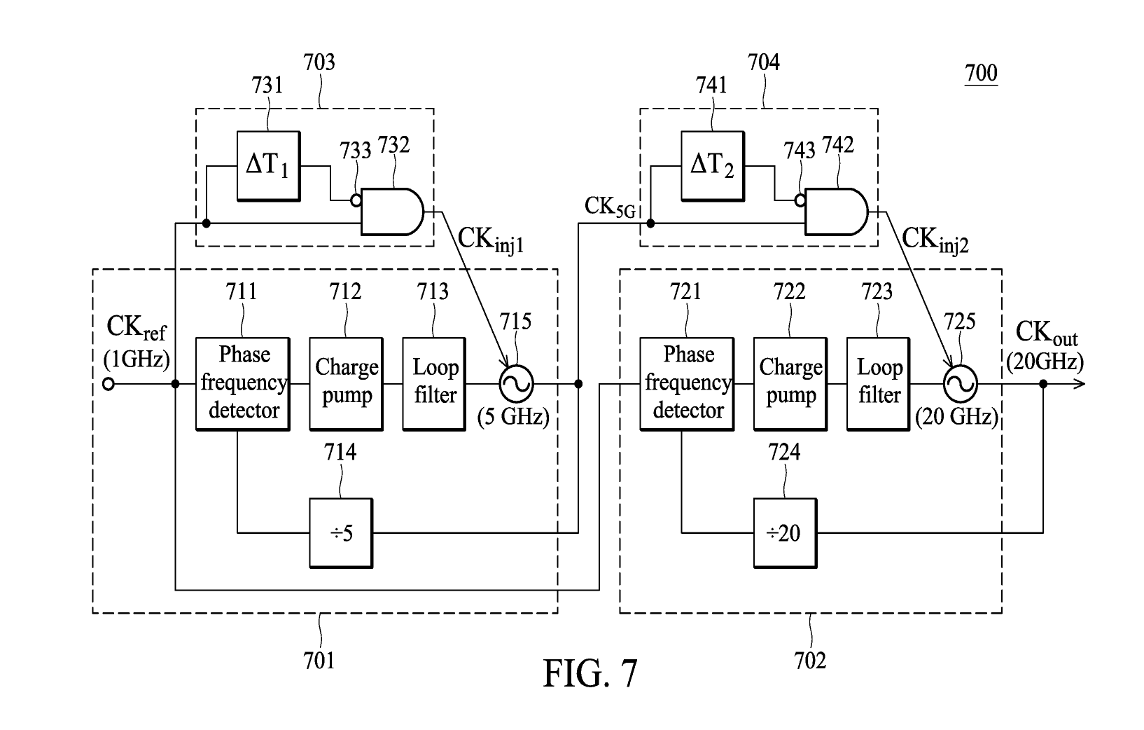

FIG. 7 shows an exemplary signal generating circuit according to another embodiment of the invention. The signal generating circuit 700 comprises two stages of cascaded phase looked loops 701 and 702, and the corresponding injection signal generating circuits 703 and 704. As shown in FIG. 7, circuit structures of the phase looked loop 701 and 702 are similar to the phase locked loop inside of the signal generating circuit 300. Each of the phase looked loops 701 and 702 comprises a phase detection circuit and an oscillator (715 and 725). The phase detection circuits are arranged to detect a phase difference between an input reference signal and a feedback signal and generate a control signal according to the detected phase difference. The oscillators generate the output signals according to the corresponding control signal and injection signal. The phase detection circuits in phase looked loops 701 and 702 comprises the phase frequency detectors 711 and 721, charge pumps 712 and 722, loop filters 713 and 723 and the divider 714 and 724, respectively. Operations of the phase frequency detectors 711 and 721, charge pumps 712 and 722, loop filters 713 and 723 and the dividers 714 and 724 are similar to the phase frequency detector 311, charge pump 312, loop filter 313 and the divider 314 as previously illustrated, and are omitted here for brevity.

As shown in FIG. 7, the phase looked loop 701 first generates an output signal CK_{5G} according to the input reference signal CK_{ref}, where an oscillation frequency of the output signal CK_{5G} is 5 GHz, which is five times that of the oscillation frequency (1 GHz) of the input reference signal CK_{ref}. Next, the phase looked loop 702 generates an output signal CKₒᵤₜ according to the input reference signal CK_{ref}. An oscillation frequency of the output signal CKₒᵤₜ is 20 GHz, which is 20 times that of the input reference signal CK_{ref}. It is noted that the phase looked loop 702 may also the output signal CKₒᵤₜ having 4 times that of oscillation frequency of the output signal CK_{5G} accordingly. In this manner, an output signal oscillated at 20 GHz may also be obtained. Based on this design concept, the bandwidth of the loop filter (such as the loop filter 723) and the divisor of the divider (such as the divider 724) coupled between cascaded phase locked loops may be flexibly designed according to a ratio of the output frequency to the input frequency and the invention is not limited thereto.

According to an embodiment of the invention, in order to mitigate the phase noise in oscillators 715 and 725, the injection signal generating circuits 703 and 704 generate and inject the injection signals CKᵢₙⱼ₁ and CKᵢₙⱼ₂ into the oscillators 715 and 725, respectively. The frequency of the injection signal CKᵢₙⱼ₁ does not equal to the oscillation frequency of the oscillator 715, and the frequency of the injection signal CKᵢₙⱼ₂ does not equal to the oscillation frequency of the oscillator 725. As an example, the injection signal CKᵢₙⱼ₁ may be a sub-harmonic signal of the output signal CK_{5G}, and the injection signal CKᵢₙⱼ₂ may be a sub-harmonic signal of the output signal CKₒᵤₜ.

As shown in FIG. 7, the injection signal generating circuits 703 and 704 may, respectively, comprise delay units 731 and 741, AND gates 732 and 742 and inverters 733 and 743. The delay units 731 and 741 respectively delays the injection reference signals for the time periods ΔT₁ and ΔT₂. According to an embodiment of the invention, the delay units 731 and 741 may respectively delay injection reference signals for the time period as long as half of the period length of the output signals CK_{5G} and CKₒᵤₜ. Thus, in the embodiment, the delay time period ΔT₁ of the delay unit 731 may be designed by setting ΔT₁=100 ps, and the delay time period ΔT₂ of the delay unit 741 may be designed by setting ΔT₂=25 ps. The inverters 733 and 743 are arranged to respectively invert the delayed injection reference signals. The AND gates 732 and 742 comprises two input terminals receiving the corresponding injection reference signal and the delayed and inverted injection reference signal, respectively, and perform AND operation thereon to generate the injection signals CKᵢₙⱼ₁ and CKᵢₙⱼ₂. It is noted that the injection signal generating circuits 703 and 704 may also be designed according to the injection signal generating circuit 403 as shown in FIG. 4. In addition, in the embodiments of the invention, the injection signal generating circuit is not limited to the designs as shown in FIG. 4 and FIG. 7. Those who are skilled in this technology can still make various alterations and modifications without departing from the scope and spirit of this invention to implement the injection signal generating circuit having substantially the same function according to different logic gates and electronic components. Therefore, the scope of the present invention shall be defined and protected by the following claims and their equivalents.

In addition, it is noted that the pulse width may not be exactly equal to half of the period length of the output signal and 50% inaccuracy may be tolerable. Therefore, the pulse width of the injection signal may be designed from 25% to 75% of the period length of the output signals CK_{5G} and CKₒᵤₜ, while still being able to reduce the phase noise of the oscillator.

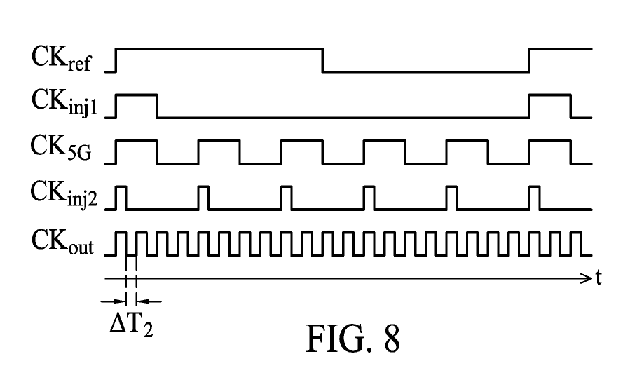

According to an embodiment of the invention, the injection reference signal of the injection signal generating circuit 703 is a sub-harmonic signal of the output signal CK_{5G}. As shown in FIG. 7, the injection reference signal of the injection signal generating circuit 703 is the reference signal CK_{ref}, oscillating at 1 GHz. The injection reference signal of the injection signal generating circuit 704 is a sub-harmonic signal of the output signal CKₒᵤₜ. In the embodiment of the invention, the output signal CK_{5G} of a previous stage of the phase locked loop 701 is used as the injection reference signal. FIG. 8 shows signal waveforms according to the embodiment of the invention. As shown in the figure, the injection signal generating circuit 703 generates, at each rising edge of the injection reference signal CK_{ref}, a pulse with a width substantially equal to half of a period length of the output signal CK_{5G} as the injection signal CKᵢₙⱼ₁. The injection signal generating circuit 704 generates, at each rising edge of the injection reference signal CK_{5G}, a pulse with a width substantially equal to half of a period length of the output signal CKₒᵤₜ as the injection signal CK_{inj 2}. When respectively performing the Fourier transform on the injection signals CKᵢₙⱼ₁ and CKᵢₙⱼ₂, it is shown that energy exists at the oscillation frequencies of the oscillators 715 and 725. FIG. 6c shows an exemplary frequency spectrum of the injection signal CKᵢₙⱼ₂ generated by the injection signal generating circuit 704 according to the embodiment of the invention. As shown in FIG. 6c, energy exists at 20 GHz frequency component in the frequency spectrum, where frequency domain signal Sᵢₙⱼ₂(ω) is obtained by performing the Fourier transforming on the injection signal CKᵢₙⱼ₂.

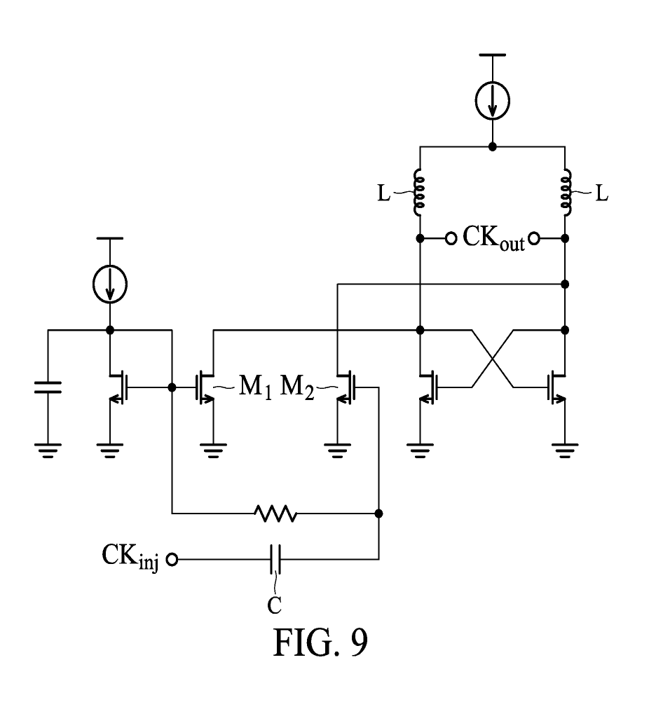

According to an embodiment of the invention, the oscillator (such as the oscillator 202, 302, 715 or 725) may be any kind of injected controlled oscillator. As an example, the oscillator may be an injected voltage controlled oscillator (or called the injection locked voltage controlled oscillator). FIG. 9 shows a circuit diagram of an oscillator according to an embodiment of the invention. As shown in the figure, the injected voltage controlled oscillator comprises an inductor capacitor oscillator and a pair of transistors M₁ and M₂ to receive the injection signal CKᵢₙⱼ.

It is noted that the performance of the phase noise suppression degrades when the frequency ratio of the output signal of the phase locked loop to the injection reference signal of the injection signal generating circuit is too large. Therefore, according to the embodiments of the invention, when the expected frequency multiple of the phase locked loop exceeds a predetermined threshold, the frequency multiple may be factorized. The phase locked loop may be implemented by a plurality of stages as shown in FIG. 7 according to the factorization result, so that the frequency ratio of the output signal to the injection reference signal in each stage does not exceed the predetermined threshold. In this way, the expected output frequency multiple is achieved and efficient phase noise suppression performance is maintained.

As an example, according to another embodiment of the invention, the signal generating circuit may comprise a first stage of circuit coupled to a second stage of circuit, and generate a high frequency output signal according to an input reference signal. The first stage of circuit comprises a first phase locked loop (as an example, the phase locked loop 701) and a first injection signal generating circuit (as an example, the injection signal generating circuit 703). The first phase locked loop is arranged to detect a phase difference between the input reference signal and a first feedback signal to generate a first control signal. The first phase locked loop comprises a first injected controlled oscillator, arranged to generate a first output signal according to the first control signal and a first injection signal. The first feedback signal is generated according to the first output signal. A frequency of the first output signal is an integer multiple of a frequency of the first feedback signal. The first injection signal generating circuit is coupled to the first injected controlled oscillator and generates the first injection signal according to a first injection reference signal. An oscillation frequency of the first injected controlled oscillator is larger than and is an integer multiple of a frequency of the first injection signal

The second stage of circuit comprises a plurality of stages of cascaded phase locked loops (as an example, by cascading a plurality of stages of the phase locked loop 702) and a plurality of stages of the injection signal generating circuits, each corresponding to one of the phase locked loops (as an example, the injection signal generating circuit 704 coupled to the phase locked loops 702). Each stage of the injection signal generating circuit is coupled to an injected controlled oscillator of the corresponding phase locked loop and generates an injection signal to the corresponding injected controlled oscillator. The second stage of circuit outputs an output signal at the last stage of the injected controlled oscillator as the high frequency output signal. An oscillation frequency of each stage of injected controlled oscillator is larger than and is an integer multiple of a frequency of the injection signal generated by the corresponding injection signal generating circuit.

The first injection signal generating circuit receives the input reference signal as the first injection reference signal and generates, at each rising edge, each falling edge, or each rising edge and each falling edge of the first injection reference signal, a pulse with a width substantially equal to half of a period length of the first output signal as the first injection signal. The first stage of the injection signal generating circuit in the second stage of circuit receives the first output signal as a corresponding injection reference signal and generates, at each rising edge, each falling edge, or each rising edge and each falling edge of the first output signal, a pulse with a width substantially equal to half of a period length of an output signal of the first stage of injected controlled oscillator in the second stage of circuit as the corresponding injection signal. Each of the remaining stages of the injection signal generating circuit in the second stage of circuit receives an output signal of a previous stage of the phase locked loop as a corresponding injection reference signal and generates, at each rising edge, each falling edge, or each rising edge and each falling edge of the injection reference signal, a pulse with a width substantially equal to half of a period length of an output signal of the corresponding injected controlled oscillator of the injection signal generating circuit as the corresponding injection signal.

While the invention has been described by way of example and in terms of preferred embodiment, it is to be understood that the invention is not limited thereto. Those who are skilled in this technology can still make various alterations and modifications without departing from the scope and spirit of this invention. Therefore, the scope of the present invention shall be defined and protected by the following claims and their equivalents.

What is claimed is:

1. A signal generating circuit for generating an output signal comprising:
a phase detection circuit, arranged to detect a phase difference between an input reference signal and a feedback signal, and generate a control signal according to the phase difference; and
an injected controlled oscillator, arranged to receive the control signal and an injection signal, and generate the output signal according to the control signal and the injection signal, wherein a frequency of the output signal is proportional to a frequency of the input reference signal, and a frequency of the injection signal does not equal to the frequency of the output signal.

2. The signal generating circuit as claimed in claim 1, wherein the frequency of the injection signal is smaller than the frequency of the output signal.

3. The signal generating circuit as claimed in claim 1, wherein the frequency of the output signal is an integer multiple of the frequency of the injection signal.

4. The signal generating circuit as claimed in claim 1, wherein the injection signal is the input reference signal.

5. The signal generating circuit as claimed in claim 1, wherein the injection signal comprises a frequency component at an oscillation frequency of the injected controlled oscillator.

6. The signal generating circuit as claimed in claim 1, wherein the phase detection circuit further comprises:
a phase frequency detector, arranged to detect the phase difference between the input reference signal and the feedback signal, and generate a phase error signal according to the phase difference;
a charge pump, arranged to generate a current signal according to the phase error signal;
a loop filter, arranged to receive and convert the current signal into the control signal; and
a feedback divider, arranged to generate the feedback signal according to the output signal, wherein the frequency of the output signal is a multiple of a frequency of the feedback signal.

7. The signal generating circuit as claimed in claim 1, further comprises an injection signal generating circuit, arranged to generate the injection signal according to an injection reference signal, wherein the injection signal comprises a plurality of pulses, and a width of each pulse is between 25% to 75% of a period length of the output signal.

8. The signal generating circuit as claimed in claim 7, wherein the width is half of the period length of the output signal.

9. The signal generating circuit as claimed in claim 1, further comprising an injection signal generating circuit, arranged to generate the injection signal according to an injection reference signal, wherein the injection signal generating circuit generates, at each rising edge or each falling edge of the injection reference signal, a pulse with a width substantially equal to half of a period length of the output signal as the injection signal.

10. The signal generating circuit as claimed in claim 1, further comprising an injection signal generating circuit, arranged to generate the injection signal according to an injection reference signal, wherein the injection signal generating circuit generates, at each rising edge and falling edge of the injection reference signal, a pulse with a width substantially equal to half of a period length of the output signal as the injection signal.

11. The signal generating circuit as claimed in claim 9, wherein the injection signal generating circuit comprises a delay unit and an XOR gate, the delay unit delays the injection reference signal for a time period having a length equal to half of the period length, and the XOR gate comprises two input terminals receiving the injection reference signal and the delayed injection reference signal, respectively, and performs XOR operation thereon to generate the injection signal.

12. The signal generating circuit as claimed in claim 10, wherein the injection signal generating circuit comprises a delay unit, an inverter and an AND gate, the delay unit delays the injection reference signal for a time period having a length equal to half of the period length, the inverter inverts the delayed injection reference signal, and the AND gate comprises two input terminals receiving the injection reference signal and the delayed and inverted injection reference signal, respectively, and performs AND operation thereon to generate the injection signal.

13. A signal generating circuit for generating an output signal comprising:
a first phase detection circuit, arranged to detect a phase difference between a first input reference signal and a first feedback signal, and generate a first control signal according to the phase difference;
a second phase detection circuit, arranged to detect a phase difference between a second input reference signal and a second feedback signal, and generate a second control signal according to the phase difference;
a first injected controlled oscillator, coupled between the first phase detection circuit and the second phase detection circuit and arranged to receive the first control signal and a first injection signal, and generate a first output signal according to the first control signal and the first injection signal, wherein a frequency of the first output signal is proportional to a frequency of the first input reference signal, and a frequency of the first injection signal does not equal to the frequency of the first output signal; and
a second injected controlled oscillator, coupled to the second phase detection circuit and arranged to receive the second control signal and a second injection signal, and generate a second output signal as the output signal according to the second control signal and the second injection signal, wherein the second input reference signal is one of the first input reference signal or the first output signal, a frequency of the second output signal is larger than and proportional to a frequency of the second input reference signal, and a frequency of the second injection signal does not equal to the frequency of second first output signal.

14. The signal generating circuit as claimed in claim 13, wherein the frequency of the first injection signal is smaller than the frequency of the first output signal, and the frequency of the second injection signal is smaller than the frequency of the second output signal.

15. The signal generating circuit as claimed in claim 13, wherein the frequency of the first output signal is an integer multiple of the frequency of the first injection signal, and the frequency of the second output signal is an integer multiple of the frequency of the second injection signal.

16. The signal generating circuit as claimed in claim 13, wherein the first injection signal is the first input reference signal, and the second injection signal is the first output signal.

17. The signal generating circuit as claimed in claim 13, wherein the first injection signal comprises a frequency component at an oscillation frequency of the first injected controlled oscillator, and the second injection signal comprises a frequency component at an oscillation frequency of the second injected controlled oscillator.

18. The signal generating circuit as claimed in claim 13, wherein the first injection signal comprises a plurality of first pulses, and a width of each first pulse is between 25% to 75% of a period length of the first output signal, and the second injection signal comprises a plurality of second pulses, and a width of each second pulse is between 25% to 75% of a period length of the second output signal.

19. The signal generating circuit as claimed in claim 18, wherein the width of the first pulse is half of the period length of the first output signal, and the width of the second pulse is half of the period length of the second output signal.

20. The signal generating circuit as claimed in claim 13, further comprising:
a first injection signal generating circuit, coupled to the first injected controlled oscillator and arranged to generate the first injection signal according to a first injection reference signal; and
a second injection signal generating circuit, coupled to the second injected controlled oscillator and arranged to generate the second injection signal according to a second injection reference signal, wherein the first injection reference signal is the first input reference signal and the second injection reference signal is the first output signal.

21. The signal generating circuit as claimed in claim 20, wherein the first injection signal generating circuit generates, at each rising edge or each falling edge of the first injection reference signal, a first pulse with a width substantially equal to half of a period length of the first output signal as the first injection signal, and the second injection signal generating circuit generates, at each rising edge or each falling edge of the second injection reference signal, a second pulse with a width substantially equal to half of a period length of the second output signal as the second injection signal.

22. The signal generating circuit as claimed in claim 20, wherein the first injection signal generating circuit generates, at each rising edge and falling edge of the first injection reference signal, a first pulse with a width substantially equal to half of a period length of the first output signal as the first injection signal, and the second injection signal generating circuit generates, at each rising edge and falling edge of the second injection reference signal, a second pulse with a width substantially equal to half of a period length of the second output signal as the second injection signal.

23. A signal generating circuit for generating a high frequency output signal according to an input reference signal comprising:
a first stage of circuit, comprising:
a first phase locked loop, arranged to detect a phase difference between the input reference signal and a first feedback signal to generate a first control signal and comprising a first injected controlled oscillator, arranged to generate a first output signal according to the first control signal and a first injection signal, wherein the first feedback signal is generated according to the first output signal and a frequency of the first output signal is an integer multiple of a frequency of the first feedback signal; and
a first injection signal generating circuit, coupled to the first injected controlled oscillator and generating the first injection signal according to a first injection reference signal, wherein an oscillation frequency of the first injected controlled oscillator is larger than and is an integer multiple of a frequency of the first injection signal; and
a second stage of circuit, coupled to the first stage of circuit and comprising a plurality of stages of cascaded phase locked loops and a plurality of stages of the injection signal generating circuits each corresponding to one of the phase locked loops, wherein each stage of the injection signal generating circuit is coupled to an injected controlled oscillator of the corresponding phase locked loop and generates an injection signal to the corresponding injected controlled oscillator, and the second stage of circuit outputs an output signal at the last stage of the injected controlled oscillator as the high frequency output signal, and wherein an oscillation frequency of each stage of injected controlled oscillator is larger than and is an integer multiple of a frequency of the injection signal generated by the corresponding injection signal generating circuit.

24. The signal generating circuit as claimed in claim 23, wherein the first injection signal generating circuit receives the input reference signal as the first injection reference signal and generates, at each rising edge of the first injection reference signal, a pulse with a width substantially equal to half of a period length of the first output signal as the first injection signal, and the first stage of the injection signal generating circuit in the second stage of circuit receives the first output signal as a corresponding injection reference signal and generates, at each rising edge of the first output signal, a pulse with a width substantially equal to half of a period length of an output signal of the first stage of injected controlled oscillator in the second stage of circuit as the injection signal, and each of the remaining stages of the injection signal generating circuit in the second stage of circuit receives an output signal of a previous stage of the phase locked loop as a corresponding injection reference signal and generates, at each rising edge of the injection reference signal, a pulse with a width substantially equal to half of a period length of an output signal of the corresponding injected controlled oscillator as the corresponding injection signal.

25. The signal generating circuit as claimed in claim 23, wherein the first injection signal generating circuit receives the input reference signal as the first injection reference signal and generates, at each rising edge and falling edge of the first injection reference signal, a pulse with a width substantially equal to half of a period length of the first output signal as the first injection signal, and the first stage of the injection signal generating circuit in the second stage of circuit receives the first output signal as a corresponding injection reference signal and generates, at each rising edge and falling edge of the first output signal, a pulse with a width substantially equal to half of a period length of an output signal of the first stage of injected controlled oscillator in the second stage of circuit as the injection signal, and each of the remaining stages of the injection signal generating circuit in the second stage of circuit receives an output signal of a previous stage of the phase locked loop as a corresponding injection reference signal and generates, at each rising edge and falling edge of the injection reference signal, a pulse with a width substantially equal to half of a period length of an output signal of the corresponding injected controlled oscillator as the corresponding injection signal.
